(19) United States
(12) Patent Application Publication
(10) Pub. No.: US 2025/0306068 A1
(43) Pub. Date: Oct. 2, 2025

(54) METHOD FOR DETECTING A FAILURE OF A RECTIFIER

(71) Applicant: MAHLE International GmbH, Stuttgart (DE)

(72) Inventor: Zan Batistic, Sempeter pri Gorici (SI)

(21) Appl. No.: 19/093,212

(22) Filed: Mar. 27, 2025

(30) Foreign Application Priority Data
Mar. 28, 2024 (EP) 24167192.4

(51) Int. Cl. G01R 23/15; H02M 7/06

(52) U.S. Cl. CPC G01R 23/15; H02M 7/06

(57) ABSTRACT

A method of detecting a failure of a rectifier of an electrical generator includes determining a frequency tolerance band based on one of the phase voltages and determining a dominant frequency based on a rectified summed output voltage. If the dominant frequency is not within the frequency tolerance band, the rectifier is failed.

### CROSS-REFERENCE TO RELATED APPLICATION

This application claims priority to European Patent Application No. EP24167192.4, filed on Mar. 28, 2024, the contents of which is hereby incorporated by reference in its entirety.

### TECHNICAL FIELD

The invention relates to a method for detecting a failure of a rectifier of an electric generator, especially of an alternator of a vehicle, according to the generic term of claim 1. The invention also relates to the electrical generator for carrying out the method.

### BACKGROUND

An electrical generator—for example a vehicle alternator—usually comprises a rotor and a stator. The stator provides several individual phase voltages depending on the number of its turns, wherein the phase voltages are then summed and rectified in a rectifier to an output voltage. A voltage regulator then controls the output voltage and provides it, for example, for charging a battery. The voltage regulator can also detect over-voltage faults and/or under-voltage faults and/or phase regulation faults and/or field excitation overcurrent and/or field excitation open circuit and/or mechanical faults.

Faults are detected by monitoring different voltage amplitudes and voltage drops in the electrical generator. A fault is detected when a fault condition is present for longer than the defined confirmation interval. The faults are then communicated to the vehicle via a communication protocol or a charging fault indicator. However, most voltage regulators are not able to detect the failure of a single diode or a rectifier switching element of the rectifier. This is because generic voltage regulators cannot reliably distinguish between the high voltage ripple caused by a high load and a high speed condition and the high voltage ripple caused by a rectifier failure.

U.S. Pat. No. 4,178,546 A proposes a method for detecting a rectifier failure that relies exclusively on the output voltage ripple signal. The failure of the rectifier is detected if the ripple frequency spectrum changes so that the f/6 frequency component—or different ratios for different failure modes—is presented. The method is disadvantageously not sufficiently robust because when the rectifier fails, the original amplitude of the ripple frequency of the output voltage decreases significantly and the new dominant frequency component caused by the rectifier failure becomes dominant. Hence, the original amplitude of the ripple frequency of the output voltage is difficult to detect.

### SUMMARY

In this context, the alternator represents a potentially critical system component that can require a service visit to the workshop in the event of a failure. Accordingly, rectifier failures should be predicted as early as possible and communicated to the vehicle operator.

It is therefore the object of the invention to provide an improved or at least alternative embodiment for a method for detecting a failure of a rectifier of an electrical generator of the generic type, in which the described disadvantages are overcome. It is also the object of the invention to provide a corresponding electrical generator.

These objects are solved according to the invention by the subject matter of the independent claims. Advantageous embodiments are the subject of the dependent claims.

The present invention is based on the general idea of a comparison of signal frequencies of the phase voltage signal and the output voltage signal to detect the failure of the rectifier caused by a short circuit or an open circuit of a diode or a rectifier switching element of the rectifier.

The method according to the invention is provided for detecting a failure of a rectifier of an electric generator, in particular of an alternator of a vehicle. In the method, the rectifier rectifies and sums up a plurality of phase voltages associated with the individual phases of the electrical generator to an output voltage of the electrical generator. According to the invention, a first preliminary step and a second preliminary step are carried out simultaneously or one after another in any order. Subsequently, a comparison step is carried out in the method. In the first preliminary step, an output voltage signal limited to a predefined time interval is extracted i.e. captured from the output voltage. Then, a frequency distribution of the output voltage signal is calculated from the output voltage signal by means of a frequency analysis algorithm, in particular by means of a Fast-Fourier-Transform. A dominant frequency i.e. a dominant frequency component with the highest amplitude is then determined from the frequency distribution of the output voltage signal. In the second preliminary step, a phase voltage signal limited to a predefined time interval is extracted i.e. captured from one of the phase voltages i.e. from the single phase voltage. A mean frequency is then calculated from the phase voltage signal and a frequency tolerance band is calculated based on the mean frequency and/or on a frequency range of phase frequencies stored in a buffer. In the comparison step, it is checked whether the dominant frequency of the output voltage signal is within the frequency tolerance band of the phase voltage signal. Depending on whether the dominant frequency of the output voltage signal is within the frequency tolerance band of the phase voltage signal or not, it is determined whether there is a failure of the rectifier or not.

A permanent undetected failure of the rectifier of the electrical generator can be problematic and should therefore be detected and communicated to the vehicle operator at an early stage. In the method according to the invention, the failure of at least one diode of the rectifier or at least one rectifier switching element of the rectifier is determined by comparing a ripple frequency of the output voltage and a phase frequency of the single phase voltage. The ripple frequency of the output voltage is thereby the frequency of the remaining i.e. residual ripple of the output voltage after summing and rectifying the phase voltages. The phase frequency of the single phase voltage is the frequency of the respective phase voltage.

During operation of the electric generator, the first preliminary step, the second preliminary step and the comparison step can be carried out continuously with a defined time interval. In other words, a plurality of iterations can be carried out in the method with a defined time interval. Thereby, the output voltage signal can be analyzed continuously in real time in predefined time windows i.e. intervals. Adventitiously, the failure of the rectifier of the electrical generator can be detected immediately and at an early stage.

The ratio between the ripple frequency of the output voltage and the phase frequency of the single phase voltage is linked to the physical properties of the generator—i.e. the number of stator phases of the stator—and remains constant over the entire life of the electrical generator. When a diode or rectifier switching element fails, the relationship between the ripple frequency of the output voltage and the phase frequency of the single phase voltage changes. Accordingly, the failure of the diode or the rectifier switching element and thus the failure of the rectifier can be reliably detected. The failure of the diode or the rectifier switching element can be in particular a short circuit or an open circuit.

A voltage regulator of the electrical generator can be used to carry out the described method. In other words, the two preliminary steps and the comparison step can be performed by means of the voltage regulator of the electric generator. The output voltage and the single phase voltage can be detected at the voltage regulator of the electric generator.

The ripple frequency of the output voltage or the dominant frequency of the output voltage signal are determined in the first preliminary step. The output voltage corresponds to the summed and rectified voltage of the electrical generator. The output voltage is a direct voltage with a residual ripple. In the method, the residual ripple of the output voltage is decisive. Based on the said residual ripple, the respective frequency distribution can be determined from the output voltage or from the extracted output voltage signal by means of a frequency analysis algorithm, in particular by means of a the Fast-Fourier-Transform. The dominant frequency with the highest amplitude of the frequency distribution is then determined. Thereby, the dominant frequency corresponds to the frequency of the residual ripple of the output voltage. After determining the dominant frequency, a frequency range search can be or is performed for an expected dominant frequency based on the frequency tolerance band of the phase voltage signal. The output voltage can be controlled by the voltage regulator of the electrical generator. The output voltage can be detected at a respective terminal of the voltage regulator of the electrical generator and further processed by the voltage regulator.

The phase frequency of the respective single phase voltage is determined in the second preliminary step. The phase voltage is provided by a stator of the electrical generator and corresponds to a single-phase voltage of the stator. The respective phase voltage is thereby an alternating voltage. The number of phase voltages depends on the design of the stator. Only one of the phase voltages i.e. only one of the respective single-phase voltages is sufficient for carrying out the method. The respective phase voltage can be detected at a respective terminal of the voltage regulator of the electrical generator and further processed by the voltage regulator.

Usually, the determination of the mean frequency of the phase voltage signal is already implemented in the voltage regulator and can be used in the method for further evaluation. The determination of the mean frequency can therefore be carried out in a manner already known to the person skilled in the art. The frequency tolerance band can thereby be determined based on the mean frequency of the phase voltage signal and/or on the frequency range of the of phase frequencies stored in a buffer i.e. on the frequency range of the phase frequencies used for the mean frequency calculation i.e. the range of the recorded frequency values in the phase frequency buffer depending on the physical properties of the generator. The frequency range of the phase frequencies can be based on the frequencies which are calculated in the iterations carried out in the method and stored i.e. recorded before in a phase frequency buffer. The phase frequency buffer can contain the phase frequency values for the past N readings. Based on the phase frequency values in the buffer, the mean value and the tolerance band can be calculated.

The calculation of the frequency tolerance band can be implemented in such a way, that the constant changing of the alternator operational conditions can be taken into account. Because the change of the rotor speed changes the phase frequency and the voltage ripple frequency of the output voltage, by adaptive calculation of the tolerance band, a false-positive rectifier failure detection can be avoided. The physical properties of the generator do not change over its lifetime and can be considered i.e. taken into account via a constant factor. For example, this factor can consider how many individual phase voltages are summed up to the output voltage. The mean frequency and the frequency range of the phase frequencies stored in a buffer, on the other hand, can be used to consider the current working state of the electrical generator or the rectifier.

In the comparison step it is checked whether the dominant frequency of the output voltage signal is within the frequency tolerance band of the phase voltage signal. In other words, it is checked whether the output voltage is a result of rectification of all phase voltages. The ripple of the output voltage is caused by the respective positive and negative peaks of the respective individual phase voltages. If the rectifier is OK, all phase voltages are summed and the residual ripple includes all peaks of the respective phase voltages. Accordingly, the dominant frequency is within the frequency tolerance band. If one of the phase voltages fails due to a short circuit or an open circuit of the diode or the rectifier switching element of the rectifier, the ripple of the output voltage lacks the corresponding positive and negative peaks of the failed phase voltage. As a result, the frequency of the output voltage ripple or the dominant frequency of the output voltage signal is reduced. Accordingly, the dominant frequency is no longer within the frequency tolerance band.

If the dominant frequency of the output voltage signal is within the frequency tolerance band of the phase voltage signal, then no failure of the rectifier is detected in the method. In other words, the output voltage is composed of all phase voltages i.e. no peaks of the individual phase voltages are missing in the residual ripple of the output voltage. Accordingly, all phase voltages are provided by the rectifier since all diode or rectifier switching elements function properly. No failure has occurred in the rectifier.

If the dominant frequency of the output voltage signal is not within the frequency tolerance band of the phase voltage signal, a failure of the rectifier is detected in the method. In other words, the output voltage is not composed of all phase voltages i.e. peaks of the individual phase voltages are missing in the residual ripple of the output voltage. Accordingly, not all phase voltages are provided by the rectifier because the diode or rectifier switching element is in short circuit or open circuit. A failure has occurred in the rectifier.

Before calculating the frequency distribution, the output voltage signal can be filtered by means of a low-pass filter. In this way, high-frequency components caused by the switching of the rectifier can be removed from the output voltage signal, thereby improving the accuracy of the evaluation. Before calculating the frequency distribution, the output voltage signal can be scaled to allow effective signal monitoring over the entire voltage range. The output voltage signal can be extracted i.e. captured as an analog signal and, before calculating the frequency distribution, converted to a digital signal using an analog-to-digital converter. Before calculating the frequency distribution, the output voltage signal can be stored in a storage.

Before calculating the mean frequency and frequency tolerance band, the phase voltage signal can be filtered using the low-pass filter to remove the high-frequency components from the phase voltage signal. Before calculating the mean frequency and frequency tolerance band, the phase voltage signal can be scaled to provide effective signal monitoring over the entire voltage range. The phase voltage signal can be extracted i.e. captured as an analog signal and, before calculating the mean frequency and frequency tolerance band, transformed to a digital pulse wave signal using a comparator. The pulse wave signal can then be used to calculate the mean frequency and frequency tolerance band as described above.

The mean frequency and the frequency tolerance band can be calculated from the phase voltage signal based on a frequency distribution of the phase voltage signal. As described above, the frequency tolerance band can be calculated depending on the physical properties of the generator. The physical properties of the generator do not change over its lifetime and can be considered i.e. taken into account via a constant factor. The current working state of the electrical generator or the rectifier can be taken into account i.e. considered via the frequency distribution of the phase voltage signal.

Before calculating the frequency distribution and calculating the mean frequency and frequency tolerance band of the phase voltage signal, the output voltage signal and the phase voltage signal can be synchronized with respect to the predefined time interval. The time synchronization can ensure that the output voltage signal and the phase voltage signal are captured in the same time interval. This prevents i.e. eliminates undesired time shifts between the two signals.

The invention also relates to an electrical generator, in particular to an alternator of a vehicle, with a rectifier. The electrical generator is provided to carry out the method described above. The electrical generator can thereby contain a stator and a rotor which can interact electromagnetically with one another. In this regard, the rectifier can get a plurality of phase voltages associated with the individual phases of the electrical generator, and can sum up and rectify the plurality of voltages associated with the individual phases into an output voltage. In addition, the electrical generator can include a voltage regulator. The voltage regulator can regulate the output voltage provided by the rectifier. In particular, the method described above can be performed using the voltage regulator. To avoid repetition, reference is made at this point to the above explanations.

Further important features and advantages of the invention are apparent from the subclaims, from the drawings, and from the accompanying figure description based on the drawings.

It is understood that the above features and those to be explained below can be used not only in the combination indicated in each case, but also in other combinations or on their own, without departing from the scope of the present invention.

Preferred embodiments of the invention are shown in the drawings and will be explained in more detail in the following description, wherein identical reference signs refer to identical or similar or functionally identical components.

### BRIEF DESCRIPTION OF THE DRAWINGS

It shows, in each case schematically:

FIG. 1 shows a circuit diagram of a generator according to the invention with a rectifier;

FIG. 2 shows a diagram of a method according to the invention for detecting a failure of the rectifier of the electric generator;

FIG. 3 shows voltages depending on time in the generator according to the invention with the rectifier functions properly;

FIG. 4 shows a frequency distribution of an output voltage signal in the generator according to the invention with the rectifier functions properly;

FIG. 5 shows voltages depending on time in the generator according to the invention with the rectifier having a diode in an open circuit; and

FIG. 6 shows voltages depending on time in the generator according to the invention with the rectifier with a diode in short circuit.

### DETAILED DESCRIPTION

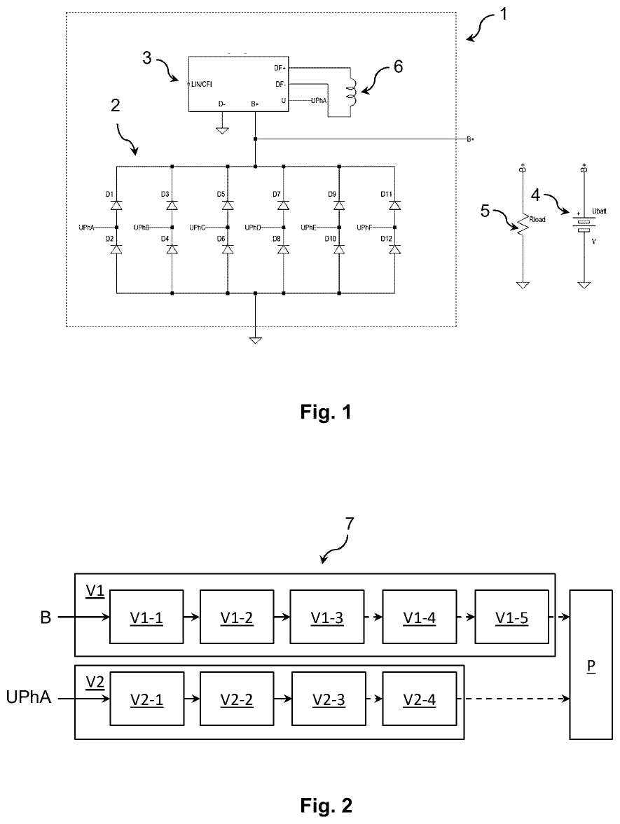

FIG. 1 shows a circuit diagram of a generator 1 according to the invention with a rectifier 2 and a voltage regulator 3. The rectifier 2 comprises several diodes D1, D2, D3, D4, D5, D6, D7, D8, D9, D10, D11, D12. A plurality of individual phase voltages UPhA, UPhB, UPhC, UPhD, UPhE, UPhF are provided to the rectifier 2 by a stator of the generator 1—not shown here—which are rectified by the rectifier 2 and summed up to an output voltage B+. The output voltage B+ can thereby be regulated by the voltage regulator 3 and provided to a battery 4 or a load 5. The voltage regulator 3 can also provide a voltage DF to a rotor 6 of the generator 1. The phase voltages UPhA, UPhB, UPhC, UPhD, UPhE, UPhF are alternating voltages, the output voltage B+ is a direct voltage with a residual ripple and the voltage DF is a pulse width modulation signal.

FIG. 2 shows a diagram of a method 7 according to the invention for detecting a failure of the rectifier 2 of the electrical generator 1. By carrying out the method 7, the output voltage B+ and one of the phase voltages UPhA, UPhB, UPhC, UPhD, UPhE, UPhF—in this case the single phase voltage UPhA—are detected via the voltage regulator 3. The output voltage B+ is then processed in a first preliminary step V1 with several individual sub-steps V1-1, V1-2, V1-3, V1-4, V1-5 and the phase voltage UPhA is processed in a second preliminary step V2 with several individual sub-steps V2-1, V2-2, V2-3, V2-4. Subsequently, a comparison step P is carried out. In FIG. 2, analog signals are marked with a solid line and digital signals are marked with a broken line.

In the first preliminary step V1, an output voltage signal limited to a predefined time interval is extracted i.e. captured from the output voltage B+. The predefined time interval can be limited to a few milliseconds, 100 milliseconds for example. The output voltage B+ is a direct voltage with a residual ripple and the output voltage signal is analog.

In sub-step V1-1, the extracted i.e. captured output voltage signal is filtered by means of a low-pass filter to remove high-frequency components caused by the switching of rectifier 1 and to increase the accuracy of the subsequent evaluation of the output voltage signal. In sub-step V1-2, the filtered output voltage signal is scaled to enable effective signal monitoring over the entire voltage range. In sub-step V1-3, the scaled output voltage signal is converted to a digital signal using an analog-to-digital converter. In sub-step V1-4, the digital output voltage signal is stored in a memory. In sub-step V1-5, a frequency distribution of the output voltage signal is calculated from the stored output voltage signal by means of a Fast-Fourier-Transform and a dominant frequency F_0—see also FIG. 4—with the highest amplitude is determined from the frequency distribution.

In the second preliminary step V2, a phase voltage signal limited to a predefined time interval is extracted i.e. captured from the phase voltage UPhA. The predefined time interval can be limited to a few milliseconds, 100 milliseconds for example. The output voltage signal and the phase voltage signal can be synchronized with respect to the predefined time interval to ensure the output voltage signal and the phase voltage signal are captured in the same time interval. The phase voltage UPhA is an alternating voltage and the phase voltage signal is analog.

In sub-step V2-1, the extracted phase voltage signal is filtered using the low-pass filter and the high-frequency components are removed from the phase voltage signal. In sub-step V2-2, the filtered phase voltage signal is scaled to enable effective signal monitoring over the entire voltage range. In sub-step V2-3, the scaled phase voltage signal is transformed to a digital pulse wave signal using a comparator. In sub-step V2-4, a mean frequency is calculated from the digital pulse-wave signal and, based on this, a frequency tolerance band FTB—see also FIG. 4. The frequency tolerance band FTB can be calculated based on the mean frequency of the phase voltage signal depending on the physical properties of the generator 1 and on a frequency range of the phase frequencies stored in a buffer i.e. the frequency range of the stored frequency values.

In the comparison step P—see also FIG. 4—it is checked whether the dominant frequency F_0 of the output voltage signal determined in sub-step V1-5 lies within the frequency tolerance band FTB of the phase voltage signal determined in sub-step V2-4. If this is the case, rectifier 1 is working properly and no failure of rectifier 1 is detected. If this is not the case, the rectifier 1 does not function properly and a failure of the rectifier 1 is detected.

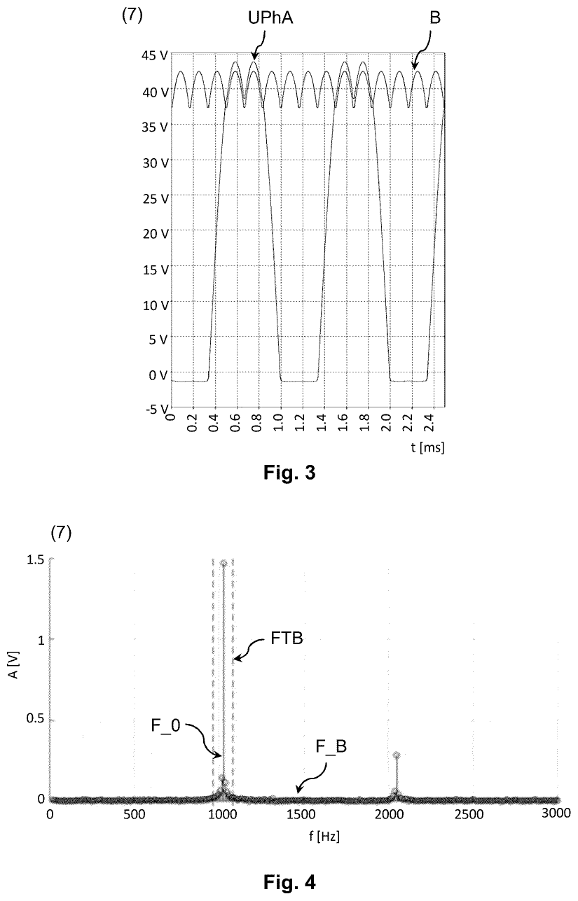

In FIG. 3 to FIG. 6 the method is described based on an example embodiment of the generator 1. In the shown exampled embodiment, the stator of the generator 1 contains 3 phase delta winding. It goes without saying, that in another embodiment the singles values would change. Nevertheless, the steps V1 and V2 and P described above remain identical independent of the concrete embodiment of the electrical generator.

FIG. 3 shows the phase voltage UPhA and the output voltage B+ depending on time t in the exampled generator 1, wherein the rectifier 2 functions i.e. works properly. As can be seen here, the residual ripple of the output voltage B+ is composed of the positive and negative peaks of the individual phase voltages UPhA, UPhB, UPhC, UPhD, UPhE, UPhF. As a result, the frequency of the ripple of the output voltage B+ is larger than the frequency of the phase voltages UPhA, UPhB, UPhC, UPhD, UPhE, UPhF by a fixed factor. In this embodiment, the said fixed factor is equal to 6.

FIG. 4 shows a frequency distribution F_B of the output voltage signal in the exampled generator 1, wherein the rectifier 2 functions i.e. works properly. The frequency distribution F_B of the output voltage signal has a dominant frequency F_0 at about 1000 Hz, which lies within the frequency tolerance band FTB of the phase voltage signal. Accordingly, the rectifier 2 functions properly and there is no failure of the rectifier 2. As described above, the calculated frequency tolerance band FTB is based on the mean frequency of the phase voltage signal and the physical characteristics of the generator 1 and on the frequency range of phase frequencies stored in a buffer i.e. the frequency range of the stored frequency values.

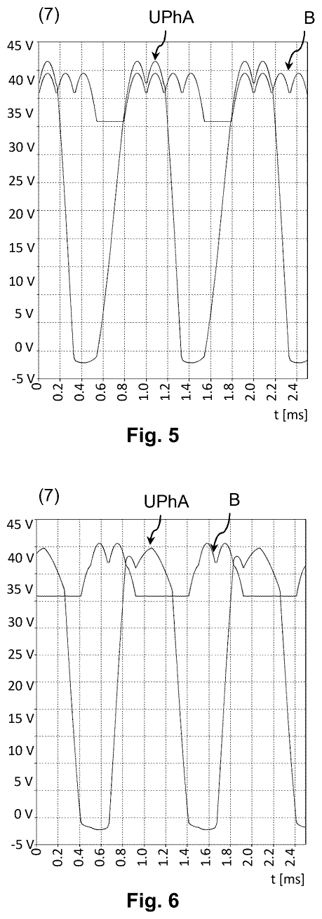

FIG. 5 shows the phase voltage UPhA and the output voltage B+ depending on time t in the exampled generator 1, wherein the rectifier 2 does not function properly. Here, a diode of the rectifier 2 is an open circuit. As can be seen, in the output voltage B+ ripples, some positive and negative peaks of the phase voltages UPhA, UPhB, UPhC, UPhD, UPhE, UPhE drop out. This also changes the frequency of the output voltage ripple and, correspondingly, the dominant frequency F_0 in the frequency distribution F_B of the output voltage signal. As a result, in the frequency domain, the dominant frequency F_0 of the output voltage signal does not lie within the frequency tolerance band FTB of the phase voltage signal. Accordingly, the rectifier 2 does not function properly and there is a failure of the rectifier 2.

FIG. 6 shows the phase voltage UPhA and the output voltage B+ depending on time t in the exampled generator 1, wherein the rectifier 2 does not function properly. Here, a diode of the rectifier 2 is in short circuit. Again, the frequency of the output voltage ripple changes and, correspondingly, the dominant frequency F_0 in the frequency distribution F_B of the output voltage signal changes. Accordingly, in the frequency domain, the dominant frequency F_0 of the output voltage signal does not lie within the frequency tolerance band FTB of the phase voltage signal. Accordingly, the rectifier 2 does not function properly and there is a failure of the rectifier 2.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “various embodiments,” “with embodiments,” “in embodiments,” or “an embodiment,” or the like, means that a particular feature, structure, or characteristic described in connection with the example/embodiment is included in at least one embodiment. Thus, appearances of the phrases “examples, “in examples,” “with examples,” “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above.

It will also be understood that, although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the phrase at least one of successive elements separated by the word “and” (e.g., “at least one of A and B”) is to be interpreted the same as the term “and/or” and as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

All matter contained in the above description or shown in the accompanying drawings shall be interpreted as illustrative only and not limiting. Changes in detail or structure may be made without departing from the present disclosure.

What is claimed is:

1. A method for detecting a failure of a rectifier of an electrical generator, comprising:
determining an output voltage signal based on an output voltage measurement taken during a predefined time interval;
determining, using a frequency analysis algorithm, a frequency distribution of the output voltage signal;
determining a dominant frequency of the output voltage signal based on the frequency distribution of the output voltage signal, the dominant frequency having a greatest amplitude;
determining a phase voltage signal based on a measurement of a phase voltage from one of a plurality of phase voltages during the predefined time interval;
determining a mean frequency based on the phase voltage signal;
determining a frequency tolerance band based on the mean frequency and/or a frequency range of phase frequencies stored in a buffer;
determining whether the dominant frequency of the output voltage signal is within the frequency tolerance band of the phase voltage signal; and
determining a failure of the rectifier based on the determination of whether the dominant frequency of the output voltage signal is within the frequency tolerance band of the phase voltage signal,
wherein the rectifier rectifies and sums the plurality of phase voltages associated with individual phases of the electrical generator and provides the output voltage of the electrical generator.

2. The method according to claim 1, wherein:
no failure of the rectifier is detected if the dominant frequency of the output voltage signal is within the frequency tolerance band of the phase voltage signal, and
the failure of the rectifier is detected if the dominant frequency of the output voltage signal is not within the frequency tolerance band of the phase voltage signal.

3. The method according to claim 1, further comprising:
filtering, using a first low-pass filter, the output voltage signal before the determination of the frequency distribution, and/or
filtering, using a second low-pass filter, the phase voltage signal before the determination of the mean frequency and the frequency tolerance band.

4. The method according to claim 1, further comprising:
scaling the output voltage signal before the determination of the frequency distribution, and/or
scaling the phase voltage signal before the determination of the mean frequency and the frequency tolerance band.

5. The method according to claim 1, further comprising:
converting, using an analog-to-digital converter, the output voltage signal from an analog signal to a digital signal before the determination of the frequency distribution.

6. The method according to claim 1, further comprising:
storing the output voltage signal in a storage before the determination of the frequency distribution.

7. The method according to claim 1, further comprising:
converting, using a comparator, the phase voltage signal from an analog signal to a digital pulse wave signal, before the determination of the mean frequency and the frequency tolerance band.

8. The method according to claim 1, further comprising:
synchronizing the output voltage signal and the phase voltage signal with respect to the predefined time interval before the determination of the frequency distribution and before the determination of the mean frequency and the frequency tolerance band of the phase voltage signal.

9. The method according to claim 1, wherein the mean frequency and the frequency tolerance band are determined based on the phase voltage signal which is based on the frequency distribution of the phase voltage signal.

10. The method according to claim 1, wherein:
the measurements of the output voltage and the phase voltage are determined at a voltage regulator of the electrical generator, and/or
the determinations of the output voltage signal, the frequency distribution of the output voltage signal, the dominant frequency based on the frequency distribution of the output voltage signal, the phase voltage signal, the mean frequency, the frequency tolerance band, whether the dominant frequency of the output voltage signal is within the frequency tolerance band of the phase voltage signal, and the failure of the rectifier are carried out by a voltage regulator of the electric generator.

11. The method according to claim 1, wherein, during operation of the electric generator, the determination of the output voltage signal, the determination of the frequency distribution of the output voltage signal, the determination of the dominant frequency of the output voltage signal, the determination of the phase voltage signal, the determination of the mean frequency based on the phase voltage signal, the determination of the frequency tolerance band, the determination of whether the dominant frequency of the output voltage signal is within the frequency tolerance band of the phase voltage signal, and the determination of the failure of the rectifier are carried out continuously with a defined time interval.

12. An electrical generator, comprising:
a rectifier,
wherein the electrical generator is configured to:
determine an output voltage signal based on an output voltage measurement taken during a predefined time interval;
determine, using a frequency analysis algorithm, a frequency distribution of the output voltage signal;
determine a dominant frequency of the output voltage signal based on the frequency distribution of the output voltage signal, the dominant frequency having a greatest amplitude;
determine a phase voltage signal based on a measurement of a phase voltage from one of a plurality of phase voltages during the predefined time interval;
determine a mean frequency based on the phase voltage signal;
determine a frequency tolerance band based on the mean frequency and/or a frequency range of phase frequencies stored in a buffer;
determine whether the dominant frequency of the output voltage signal is within the frequency tolerance band of the phase voltage signal; and
determine a failure of the rectifier based on the determination of whether the dominant frequency of the output voltage signal is within the frequency tolerance band of the phase voltage signal.

13. The method according to claim 1, wherein the electrical generator is an alternator of a vehicle.

14. The method according to claim 1, wherein the frequency analysis algorithm is a Fast Fourier Transform.

15. The electrical generator according to claim 12, wherein the electrical generator is further configured to:
filter, using a first low-pass filter, the output voltage signal before the determination of the frequency distribution, and/or
filter, using a second low-pass filter, the phase voltage signal before the determination of the mean frequency and the frequency tolerance band.

16. The electrical generator according to claim 12, wherein the electrical generator is further configured to:
scale the output voltage signal before the determination of the frequency distribution, and/or
scale the phase voltage signal before the determination of the mean frequency and the frequency tolerance band.

17. The electrical generator according to claim 12, wherein the electrical generator is further configured to:
convert, using an analog-to-digital converter, the output voltage signal from an analog signal to a digital signal before the determination of the frequency distribution.

18. The electrical generator according to claim 12, wherein the electrical generator is further configured to:
store the output voltage signal in a storage before the determination of the frequency distribution.

19. The electrical generator according to claim 12, wherein the electrical generator is further configured to:
convert, using a comparator, the phase voltage signal from an analog signal to a digital pulse wave signal, before the determination of the mean frequency and the frequency tolerance band.

20. The electrical generator according to claim 12, wherein the electrical generator is further configured to:
synchronize the output voltage signal and the phase voltage signal with respect to the predefined time interval before the determination of the frequency distribution and before the determination of the mean frequency and the frequency tolerance band of the phase voltage signal.
